(19) United States
(12) Patent Application Publication
(10) Pub. No.: US 2007/0178390 A1
(43) Pub. Date: Aug. 2, 2007

(54) Exposure mask, liquid crystal display device using the same, and method of manufacturing liquid crystal display device using the same

(76) Inventors: Sung Taek Yun, Seoul (KR); Yong Gi Park, Siheung-si (KR); Yong Koo Her, Yongin-si (KR)

Correspondence Address: CANTOR COLBURN, LLP, 55 GRIFFIN ROAD SOUTH, BLOOMFIELD, CT, 06002, US

(21) Appl. No.: 11/512,450

(22) Filed: Aug. 30, 2006

(30) Foreign Application Priority Data
Jan. 27, 2006 (KR) 2006-0008920

(51) Int. Cl. G03F 1/00; G03C 5/00

(52) U.S. Cl. 430/5; 430/394

(57) ABSTRACT

An exposure mask suitable for forming a color filter for compensating for a difference in color reproduction between a reflective area and a transmissive area including first areas causing a part of a thin film to remain as a thin film pattern by controlling an incident light, second areas removing the other part of the thin film by controlling the incident light contrary to the first areas and dummy areas extended from edges of the first areas and formed such that the thin film pattern substantially corresponds to the first areas.

This application claims priority to Korean Patent Application No. 2006-0008920 filed on Jan. 27, 2006, and all the benefits accruing therefrom under 35 U.S.C. §119, the contents of which are hereby incorporated by reference in their entirety.

### BACKGROUND OF THE INVENTION

1. Field of the Invention

The present invention relates to liquid crystal display (LCD) devices, and more particularly, to an exposure mask suitable for forming a color filter for compensating for a difference in color reproduction between a reflective area and a transmissive area, an LCD device using the exposure mask and a method of manufacturing the LCD device using the exposure mask.

2. Description of the Related Art

An LCD device displays images by using electro-optical properties of liquid crystals. The LCD device includes an LCD panel for displaying the images through a pixel matrix, a driving circuit for driving the LCD panel, and a backlight unit for supplying light to the LCD panel. The LCD device is widely used ranging from small-sized display devices such as mobile communication terminals, notebook computers, monitors and LCD TVs to large-sized display devices.

The LCD device is classified according to a method of using a light source into a transmissive type using an internal light, a reflective type using an external light, and a transflective type using both the internal light and the external light. The transflective LCD device displays an image in a reflective mode if the external light is sufficient, and in a transmissive mode using a backlight unit if the external light is insufficient. Therefore, the transflective LCD device has the advantage of reducing power consumption as the reflective type and that of being not restricted to the external light as the transmissive type. For this end, each of subpixels constituting a pixel matrix of the transflective LCD device includes a transmissive area and a reflective area.

The external light incident onto the reflective area from the exterior in each subpixel of the transflective LCD device is emitted by passing sequentially through a color filter substrate, a liquid crystal layer, a reflective electrode, the liquid crystal layer and the color filter substrate. The internal light incident onto the transmissive area from the backlight unit is emitted by passing sequentially through a thin film transistor (TFT) substrate, the liquid crystal layer, and the color filter substrate. That is, the external light of the reflective area passes through the color filter twice, whereas the internal light of the transmissive area passes through the color filter once. Accordingly, there is a difference in color reproduction between the transmissive area and the reflective area and as a result a difference in luminance occurs.

### BRIEF SUMMARY OF THE INVENTION

Exemplary embodiments provide an exposure mask suitable for forming a color filter for compensating for a difference in color reproduction between a reflective area and a transmissive area, an LCD device using the exposure mask and a method of manufacturing the LCD device using the exposure mask.

One exemplary embodiment provides an exposure mask including first areas causing a part of a thin film to remain as a thin film pattern by controlling an incident light, second areas removing the other part of the thin film by controlling the incident light contrary to the first areas and dummy areas extended from edges of the first areas and formed such that the thin film pattern substantially corresponds to the first areas.

In another exemplary embodiment, the first areas may be transmission portions transmitting the incident light, the second areas may be blocking portions blocking the incident light, and the dummy areas may be dummy transmission portions extended from edges of the transmission portions.

In another exemplary embodiment, the first areas may be blocking portions for blocking the incident light, the second areas may be transmission portions for transmitting the incident light, and the dummy areas may be dummy blocking portions extended from the edges of the blocking portions.

In another exemplary embodiment, the dummy areas may be extended from the first areas in substantially one direction. The dummy areas extended from the first areas may be connected to each other and a portion of the second area may be disposed therebetween.

In another exemplary embodiment, there is provided a method of manufacturing an LCD device, the method including forming a color photoresist on an insulating substrate, exposing the color photoresist using an exposure mask having first and second areas controlling an incident light contrary to each other and dummy areas extended from edges of the first areas, and forming a color filter substantially corresponding to the first areas of the exposure mask, the forming a color filter comprising developing the color photoresist.

In another exemplary embodiment, the exposing the color photoresist may include exposing a part of the color photoresist through the first areas comprising transmission portions, blocking exposure of the other part of the color photoresist through the second areas comprising blocking portions, and increasing an amount of exposure of the edges of the first areas through dummy areas comprising dummy transmission portions.

In another exemplary embodiment, the exposing the color photoresist may include blocking exposure of a part of the color photoresist through the first areas comprising blocking portions, exposing the other part of the color photoresist through the second areas comprising transmission portions and decreasing the exposure of the first areas through the dummy areas comprising blocking portions.

In another exemplary embodiment, the dummy areas extended between adjacent first areas are connected to each other and a portion of the second area is disposed therebetween.

In another exemplary embodiment, the forming the color filter may further include forming the color filter in a subpixel area among subpixel areas, the subpixel area including a reflective area and a transmissive area and forming slits corresponding to the second areas in the reflective area of the color filter.

In another exemplary embodiment, the forming slits of the color filter may include forming the slits to be long substantially in a short or long direction of the subpixel area. The slits of the color filters may be formed to be long in a rubbing direction of an alignment layer formed on an insulating substrate on which the color filter is formed.

In another exemplary embodiment, the exposure mask may include the first areas corresponding to the color filter and a portion of the second areas disposed between the first areas, wherein the dummy areas extended from the edges of the first areas to the second areas are connected to each other to isolate the portion of the second area.

In another exemplary embodiment, there is provided an LCD device including a color filter formed according to a corresponding color in each of subpixel areas including a reflective area and a transmission area, an alignment layer formed on an insulating substrate where the color filter is formed, and a slit formed on the color filter of the reflective area to be long in a rubbing direction of the alignment layer.

In another exemplary embodiment, the slit of the color filter may be formed long substantially in a long side of each subpixel area.

### BRIEF DESCRIPTION OF THE DRAWINGS

The above and other features and advantages of the present invention will become more apparent from the following detailed description when taken in conjunction with the accompanying drawings in which:

FIG. 1 is a cross-sectional view partially illustrating an exemplary embodiment of a transflective LCD panel according to the present invention;

FIG. 2 is a plane view illustrating an exemplary embodiment of a color filter in one subpixel area according to the present invention;

FIG. 3 is a plane view illustrating another exemplary embodiment of a color filter in one subpixel area according to the present invention;

FIG. 4 is a cross-sectional view for describing an exemplary embodiment of a method of forming a color filter according to the present invention;

FIGS. 5A to 5C are plane views illustrating exemplary embodiments of exposure masks used for forming a color filter according to the present invention; and

FIG. 6 is an enlarged plane view of an exemplary embodiment of a reflective area of a color filter according to the present invention.

### DETAILED DESCRIPTION OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “lower”, “under,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “under” other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

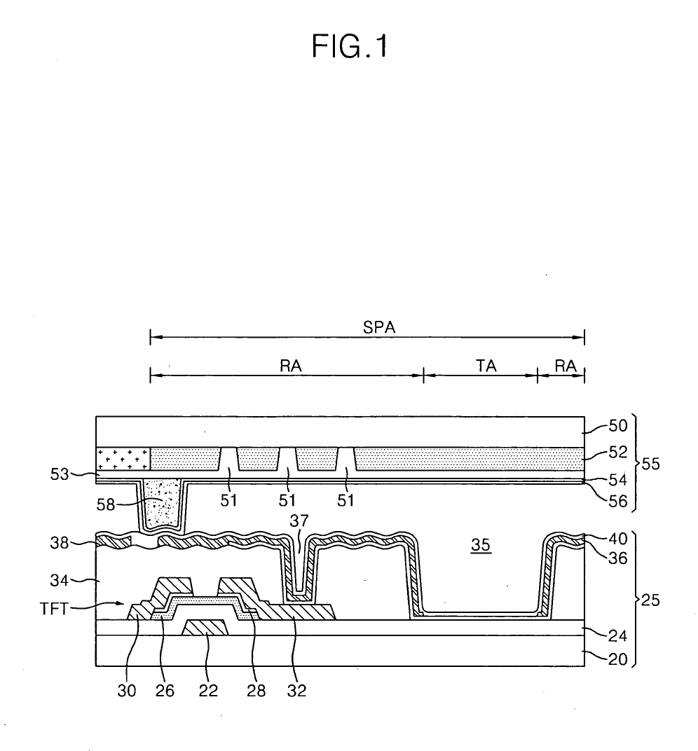

The exemplary embodiments of the present invention will now be described with reference to FIGS. 1 to 6.

FIG. 1 is a cross-sectional view illustrating an exemplary embodiment of a transflective LCD device according to the present invention.

The transflective LCD device has a structure in which a TFT substrate 25 where a TFT is formed and a color filter substrate 55 where a thin film, such as a color filter 52, is formed are assembled with a liquid crystal layer disposed therebetween.

The TFT substrate 25 includes the TFT connected to a gate line (not shown) and a data line (not shown), a pixel electrode 36 connected to the TFT and formed in each subpixel area SPA, and a reflective electrode 38 connected to the TFT, for defining a reflective area RA and a transmissive area TA of each subpixel area SPA.

The TFT includes a gate electrode 22 connected to the gate line, an active layer 26 overlapped by the gate electrode 22 with a gate insulating layer 24 disposed therebetween, a source electrode 30 connected to the data line and to one side of the active layer 26, and a drain electrode 32 connected to the other side of the active layer 26. The TFT also includes an ohmic contact layer 28 for ohmic contact between the source and drain electrodes 30 and 32 and the active layer 26. The gate electrode 22 is formed on an insulating substrate 20 together with the gate line. The active layer 26 and the ohmic contact layer 28 are formed on the gate insulating layer 24, and the source electrode 30 and the drain electrode 32 are formed together with the data line on the gate insulating layer 24 on which the active layer 26 and the ohmic contact layer 28 are formed. The TFT is connected to the pixel electrode 36 and the reflective electrode 38 through a contact hole 37 penetrating an organic insulating layer 34 formed thereon. The TFT supplies a data signal of the data line to the pixel electrode 36 and the reflective electrode 38 in response to a gate signal of the gate line.

The organic insulating layer 34 formed on the TFT includes the contact hole 37 exposing the drain electrode 32 and includes a transmissive hole 35 formed in the transmissive area TA. The transmissive hole 35 compensates for a light path difference between an external light emitted by passing through a liquid crystal layer twice in the reflective area RA and an internal light emitted by passing through the liquid crystal layer once in the transmissive area TA. The transmissive hole 35 exposes the gate insulating layer 24 by penetrating the organic insulating layer 34 and/or exposes the insulating substrate 20 by penetrating the organic insulating layer 34 and the gate insulating layer 24. An inorganic insulating layer may be formed on and/or under the organic insulating layer 34.

The pixel electrode 36 may be formed in each subpixel area SPA via the organic insulating layer 34 and the transmissive hole 35 and connected to the drain electrode 32 through the contact hole 37. In exemplary embodiments, the pixel electrode 36 may be formed of a transparent conductive material having high transmittance and transmit the internal light from a backlight unit.

In one exemplary embodiment, the reflective electrode 38 may be formed in the reflective area RA of each subpixel area SPA and connected to the drain electrode 32 through the pixel electrode 36 formed under the reflective electrode 38. An area where the reflective electrode 38 is formed in the subpixel area SPA is defined as the reflective area RA, and an area where the reflective electrode 38 is not formed, that is, an area where the pixel electrode 36 is exposed through a penetrating hole of the reflective electrode 38 is defined as the transmissive area TA. In exemplary embodiments, the reflective electrode 38 may be formed of a conductive material having high reflectance to reflect the external light. In another exemplary embodiment, to raise reflective efficiency, the surface of the organic insulating layer 34 may be formed to have an embossing pattern such that the reflective electrode 38 may also essentially include an embossing surface. In other exemplary embodiments, the outer side of the reflective electrode 38 may be formed to overlap one side of each of the gate and data lines defining the subpixel area SPA and to overlap the TFT, thereby blocking light leakage. Advantageously, a block matrix (not shown) formed on the TFT substrate 25 to prevent the light leakage may be omitted.

The color filter substrate 55 includes the color filter 52 formed on an insulating substrate 50, and a column spacer 58 and a common electrode 54 deposited on the color filter 52. The color filter substrate 55 may also include an overcoat layer 53 for planarizing the color filter 52.

The color filter 52 is formed on the insulating substrate 50 in each of red (R), green (G) and blue (B) subpixel areas to define R, G and B subpixels. The color filter 52 of each subpixel area SPA includes a plurality of slits 51 formed in the reflective area RA in order to compensate for a difference in color reproduction between the reflective area RA and the transmissive area TA. The overcoat layer 53 is formed on the color filter 52 to essentially planarize a surface of the color filter 52 by compensating for a step coverage of the color filter 52 caused by the slits 51 and a step coverage between R, G and B color filters. The column spacer 58 is formed on the overcoat layer 53 in a column shape and maintains a cell gap of a predetermined distance between the TFT substrate 25 and the color filter substrate 55 constant. The common electrode 54 is formed on the overcoat layer 53 where the column spacer 58 is formed. In exemplary embodiments, the common electrode 54 may include a transparent conductive material.

A lower alignment layer 40 and an upper alignment layer 56 rubbed in a predetermined direction to align liquid crystals may be formed on the uppermost layers contacting with the liquid crystal layer on the TFT substrate 25 and the color filter substrate 55, respectively.

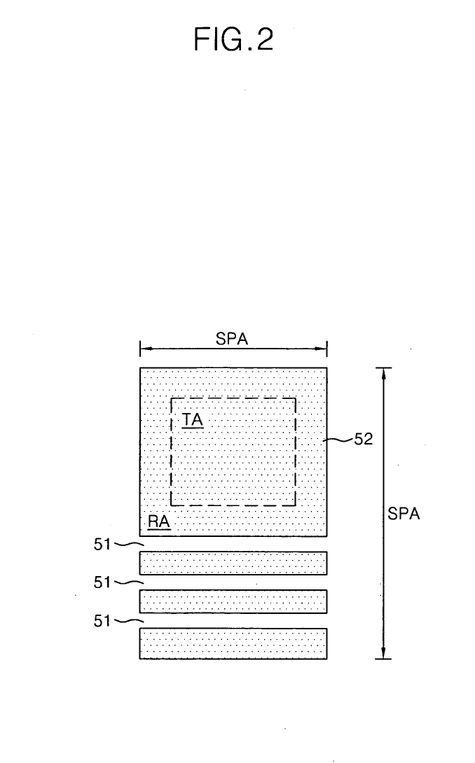

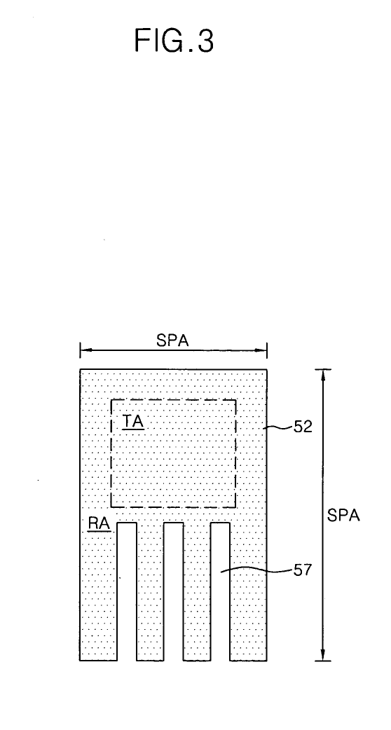

FIGS. 2 and 3 are plane views illustrating exemplary embodiments of a color filter in one subpixel area according to the present invention.

A color filter 52 in one subpixel area SPA shown in FIG. 2 includes the plurality of slits 51 formed to be long in a substantially horizontal direction in the reflective area RA, that is, in the direction of a short (or transverse) side of the subpixel area SPA. A color filter 52 in one subpixel area SPA shown in FIG. 3 includes a plurality of slits 57 formed to be long in a substantially vertical rubbing direction of an alignment layer in the reflective area RA, that is, in the direction of a long (or longitudinal) side of the subpixel area SPA.

In one exemplary embodiment, if the slits 51 of the color filter 52 are formed to be long in a horizontal direction as shown in FIG. 2 and if the upper alignment layer 56 shown in FIG. 1 has a vertical rubbing direction, there may be a rubbing defect at a stepped portion of the color filter 52 caused by the slits 51 and liquid crystals may not be properly aligned. As a result, light leakage may occur. The stepped portion of the color filter 52 may not be completely compensated for due to a wide width of the slits 51 even though it is compensated for by the overcoat layer 53 shown in FIG. 1.

In an alternative exemplary embodiment, if the slits 57 of the color filter 52 are formed to be long in a vertical direction substantially parallel to the rubbing direction as shown in FIG. 3, since an area perpendicular to the rubbing direction out of the stepped portion of the color filter 52 caused by the slits 57 is reduced, the rubbing defect may be. minimized. If the slits 57 of the color filter 52 are vertically formed to be long in the direction of the long side of the subpixel area SPA, areas (or extension in a longitudinal direction of the subpixel area SPA) of the slits 57 may be greater than when the slits 51 are formed substantially parallel to the direction of the short side of the subpixel area SPA as shown in FIG. 2. A width of the slits 57 taken in a direction substantially perpendicular to a longitudinal direction of the slits 57 may be reduced as shown in FIG. 3. If the width of the slits 57 becomes relatively narrow, since the step coverage of the color filter 52 can be sufficiently compensated for by the overcoat layer 53, the flatness of the overcoat layer 53 may be improved. Advantageously, the flatness of the common electrode 54 and upper alignment layer 56 deposited on the overcoat layer 53 may be improved and the rubbing defect caused by the step coverage can be effectively reduced or prevented. Since the column spacer 58 may be stably formed on the overcoat layer 53 of which flatness is improved, a cell gap between the TFT substrate 25 and the color filter substrate 55 may be kept substantially constant.

Hereinafter, an exemplary embodiment of a manufacturing method of the color filter will be described in detail. For simplicity, only the color filter 52 shown in FIG. 2 will be described by way of example.

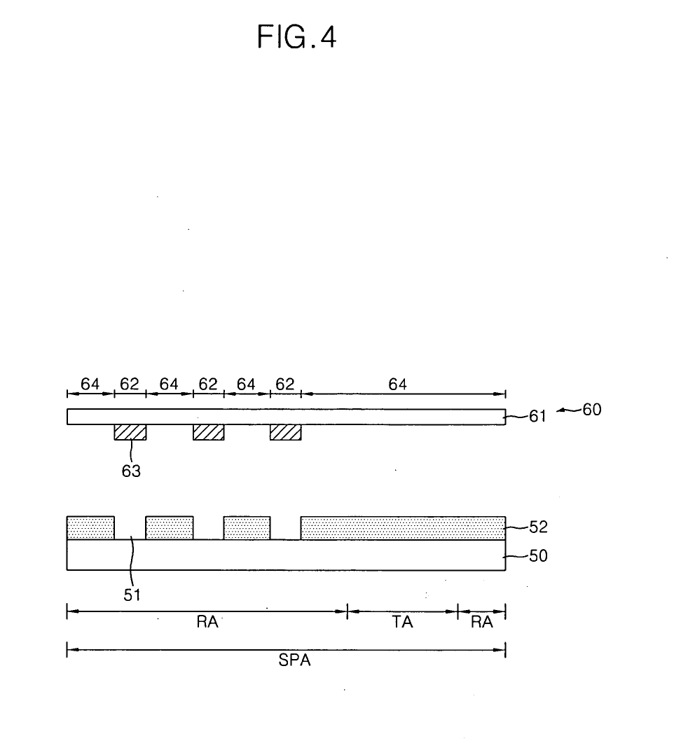

Referring to FIG. 4, a thin film, such as color photoresist layer, is deposited on the insulating substrate 50. The thin film may be colored by any one of R, G, B and any combination including at least one of the foregoing. The color photoresist may be patterned by a photolithographic process using a mask 60, to form the color filter 52. The plurality of slits 51 penetrating the color filter 52 is formed in the reflective area RA of the subpixel area SPA. The mask 60 for forming the color filter 52 includes a blocking portion 62 in which a blocking pattern 63 is formed on a substrate 61 to block incident light, such as ultraviolet rays, and a transmission portion 64 for transmitting the incident light. In one exemplary embodiment, if the color photoresist is a negative type, the color photoresist of a region exposed by ultraviolet rays through the transmission portion 64 of the mask 60 remains to form the color filter 52 and the color photoresist of a region where ultraviolet rays are blocked by the blocking portion 62 is ultimately removed by developing solutions.

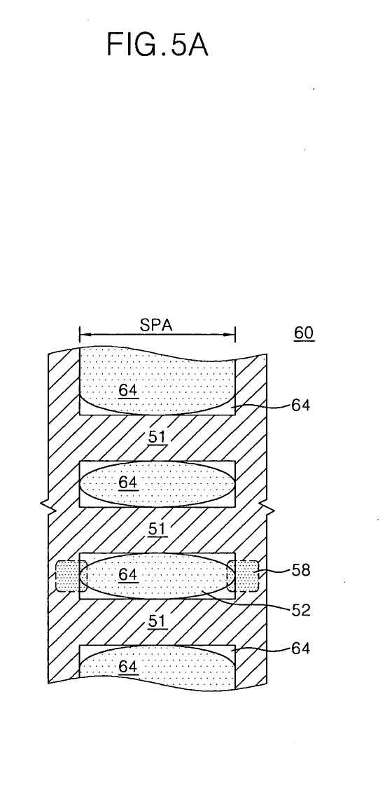

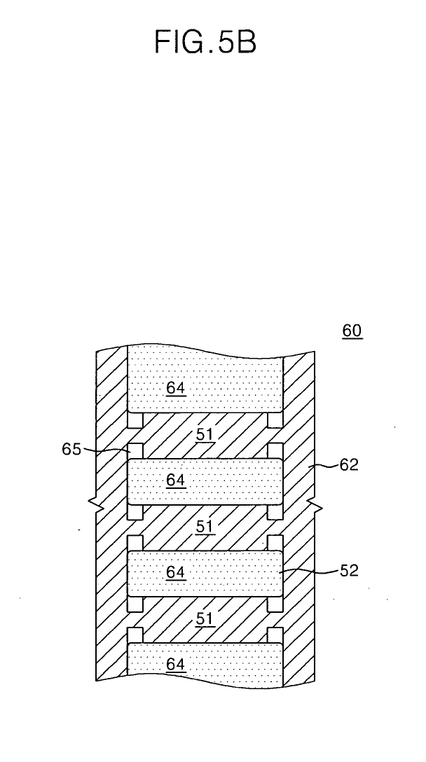

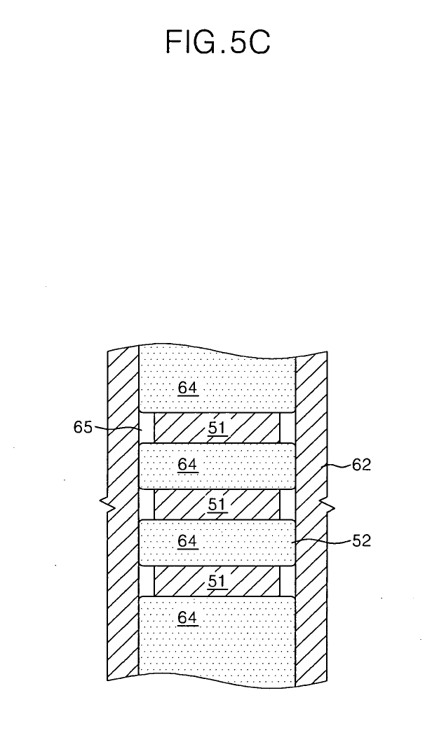

In an alternative exemplary embodiment, if an edge of the transmission portion 64 of the mask 60 is short of the amount of exposure due to diffraction of ultraviolet rays, an edge of the color filter 52 corresponding to that of the transmission portion 64 of the mask 60 may be eliminated by overetching as shown in FIG 5A. The color filter 52 may be considered as corresponding substantially in shape, size or positional placement relative to the transmission portion 64. The stepped portion of the color filter 52 is essentially increased by the overetching of the edge of the color filter 52. Advantageously, the rubbing defect may increase. When the column spacer 58 is formed on the boundary of sides of the color filter 52 having a relatively narrow width between the slits 51 in the reflective area RA as shown in FIG. 5A, the overetching of the edge of the color filter 52 may cause the column spacer 58 to be unstably formed at the stepped portion of the color filter 52 and a cell gap may become uneven.

In another alternative exemplary embodiment, the mask 60 may include dummy transparent portions 65 extended to an upper side and/or a lower side from edges or corners of the transmission portion 64 as shown in FIG. 5B. In one exemplary embodiment, if the width of the slit 51 in the color filter 52 is relatively narrow, namely, if the interval between the transmission portions 64 of the mask 60 is relatively narrow as shown in FIG. 5C, the dummy transmission portions 65 may be connected to each other, essentially forming a single dummy transmission portion 65 substantially similar in width to the slits 51. The blocking portion 62 for forming the slit 51 of the color filter 52 may be formed in an isolated form between the transmission portions 64 connected to each other through the dummy transmission portions 65. Advantageously, since ultraviolet rays are sufficiently irradiated by the dummy transmission portions 65 of the mask 60 onto the edges of the color filter 52 corresponding to the transmission portions 64, the overetching of the edges of the color filter 52 can be effectively reduced or prevented.

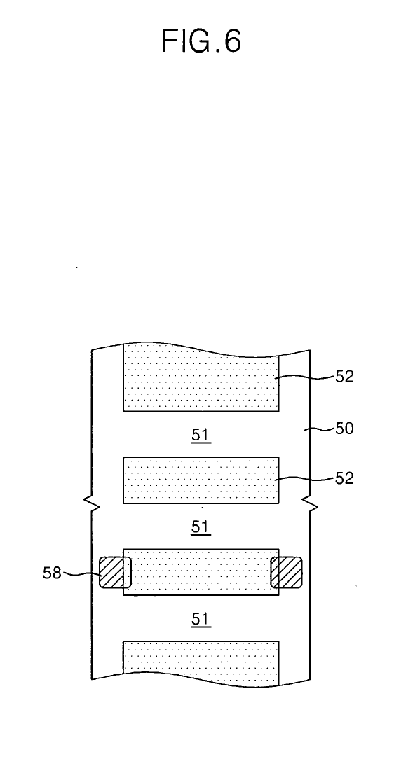

In one exemplary embodiment shown in FIG. 6, the color filter 52 may be formed in a desired form substantially corresponding to the transmission portion 64 of the mask 60 shown in FIGS. 5B and 5C without overetching its edges. The column spacer 58 may be stably formed even on a boundary of the color filter 52 having a relatively narrow width between the slits 51 of the reflective area RA. Advantageously, the cell gap may be kept uniform. Since the area of the stepped portion is decreased more than when the edge of the color filter 52 is eliminated by overetching, the rubbing defect may be reduced. Additionally, since the color filter 52 existing with a narrow width between the slits 51 of the reflective area RA may be formed to a desired area, visibility may be improved.

In another alternative exemplary embodiment, if the color photoresist is a positive type, a structure in which the blocking portion and the transmission portion are reversed may be used. Since only the color photoresist corresponding to the blocking portion of the mask remains to become the color filter, the mask includes dummy blocking portions extended from the edges of the blocking portion. The dummy blocking portions may prevent overetching of the edges of the color filter by preventing the edges of the blocking portion from being exposed by diffracted ultraviolet rays.

In exemplary embodiments, in order to form the color filter substantially corresponding to the transmission portion (or the blocking portion) of the mask, the exposure mask, the LCD device using the exposure mask, and the method of manufacturing the LCD device using the exposure mask may include a dummy transmission portion (or dummy blocking portion) extended from the edges of the transmission portion (or blocking portion), thereby effectively reducing or preventing the edges of the color filter from being eliminated or degraded by overetching. When the slits of the color filter are formed in the reflective area of the each subpixel area, the color filter existing between the slits may be formed in a desired form. Advantageously, a cell gap can be kept uniform by stably forming the column spacer on the boundary of the color filter. Moreover, since the area of the stepped portion is decreased more than when the edge of the color filter is eliminated by overetching, the rubbing defect may be reduced and picture quality may be improved. Additionally, since the color filter existing with a narrow width between the slits of the reflective area is formed to a desired area, visibility may be improved. The rubbing defect caused by the step coverage of the color filter may be minimized by forming the slit of the color filter formed in the reflective area to be long in the rubbing direction, thereby further improving the picture quality.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. An exposure mask, comprising:
first areas causing a part of a thin film to remain as a thin film pattern by controlling an incident light;
second areas removing the other part of the thin film by controlling the incident light contrary to the first areas; and
dummy areas extended from edges of the first areas and formed such that the thin film pattern substantially corresponds to the first areas.

2. The exposure mask of claim 1, wherein the first areas are transmission portions transmitting the incident light, the second areas are blocking portions blocking the incident light, and the dummy areas are dummy transmission portions extended from the edges of the transmission portions.

3. The exposure mask of claim 1, wherein the first areas are blocking portions blocking the incident light, the second areas are transmission portions transmitting the incident light, and the dummy areas are dummy blocking portions extended from the edges of the blocking portions.

4. The exposure mask of claim 1, wherein the dummy areas are extended from the first areas in substantially one direction.

5. The exposure mask of claim 1, wherein the dummy areas extended between adjacent first areas are connected to each other and a portion of the second area is disposed between the dummy areas.

6. A method of manufacturing a liquid crystal display device, comprising the steps of:
forming a color photoresist on an insulating substrate;
exposing the color photoresist using an exposure mask comprising first and second areas controlling an incident light contrary to each other and dummy areas extended from edges of the first areas; and
forming a color filter substantially corresponding to the first areas of the exposure mask, the forming a color filter comprising developing the color photoresist.

7. The method of claim 6, wherein the exposing the color photoresist comprises:
exposing a part of the color photoresist through the first areas comprising transmission portions;
blocking exposure of the other part of the color photoresist through the second areas comprising blocking portions; and
increasing an amount of exposure of the edges of the first areas through the dummy areas comprising dummy transmission portions.

8. The method of claim 6, wherein the exposing the color photoresist comprises:
blocking exposure of a part of the color photoresist through the first areas comprising blocking portions;
exposing the other part of the color photoresist through the second areas comprising transmission portions; and
decreasing the exposure of the edges of the first areas through the dummy areas comprising dummy blocking portions.

9. The method of claim 6, wherein the dummy areas extended between adjacent first areas are connected to each other and a portion of the second area is disposed therebetween.

10. The method of claim 6, wherein the forming the color filter further comprises forming the color filter in a subpixel area among subpixel areas, the subpixel area comprising a reflective area and a transmissive area and forming slits corresponding to the second areas in the reflective area of the color filter.

11. The method of claim 10, wherein the forming slits comprises forming the slits to be long substantially in a short direction of the subpixel area.

12. The method of claim 10, wherein the forming slits comprises forming the slits to be long substantially in a long direction of the subpixel area.

13. The method of claim 10, further comprising forming an alignment layer on an insulating substrate on which the color filter is formed, wherein the forming slits comprises forming the slits to be long substantially in a rubbing direction of the alignment layer.

14. The method of claim 10, wherein the exposure mask comprises the first areas corresponding to the color filter and a portion of the second areas disposed between the first areas, wherein the dummy areas extended from the edges of the first areas to the second areas are connected to each other to isolate the portion of the second areas.

15. A liquid crystal display device, comprising:
a color filter formed according to a corresponding color in each of subpixel areas comprising a reflective area and a transmission area;
an alignment layer formed on an insulating substrate where the color filter is formed; and
a slit formed on the color filter of the reflective area, the slit being long in a rubbing direction of the alignment layer.

16. The liquid crystal display device of claim 15, wherein the slit of the color filter is formed long in a substantially long side of each subpixel area.

17. The liquid crystal display device of claim 15, further comprising a overcoat layer formed on the color filter.
